(19) United States
(12) Patent Application Publication
(10) Pub. No.: US 2003/0102863 A1
(43) Pub. Date: Jun. 5, 2003

(54) Magnetic force microscopy having a magnetic probe coated with exchange coupled magnetic multiple layers

(75) Inventor: Yihong Wu, Singapore (SG)

Correspondence Address: KENYON & KENYON, 1500 K STREET, N.W., SUITE 700, WASHINGTON, DC, 20005, US

(73) Assignee: Data Storage Institute, Singapore (SG)

(21) Appl. No.: 10/095,574

(22) Filed: Mar. 13, 2002

(30) Foreign Application Priority Data
Nov. 30, 2001 (SG) 200107483-0

(51) Int. Cl. G01R 33/02

(52) U.S. Cl. 324/244; 324/249

(57) ABSTRACT

A magnetic force microscopy (MFM) probe has an elongated probe tip with a planar surface onto which a uniformly thick magnetic film is formed. The magnetic film may comprise either a seed layer, an exchanged coupled ferromagnetic/anti-ferromagnetic double layer, and a capping layer, or a seed layer, an antiferromagnetic layer, a synthetic triple layer consisting of a thin non-magnetic layer sandwiched by two ferromagnets, and a capping layer. The multiple layers are annealed below the Neel temperature of the anti-ferromagnetic layer and field cooled to establish an unidirectional exchange bias along the tip surface. The coated portion of the tip is made sufficiently long so that the interaction between the tip and sample mainly happens at the bottom end of the tip. The thickness of the thin non-magnetic layer and the two ferromagnetic layers in the synthetic triple layer are chosen such that the two ferromagnetic layers are anti-ferromagnetically coupled, but at the mean time the triple layer as a whole has a net magnetic moment. In both cases, the magnetization of the ferromagnets are strongly stabilized at certain fixed directions and thus, in ideal case, the flux leakage at the middle of the coated portion is negligible; these result in a much higher resolution. As the magnetization is pinned by the exchange coupling mechanism, the total magnetic moment of the tip can be reduced to reduce the undesirable effect of the tip to the specimen.

This invention relates to magnetic force microscopy and more particularly to a probe for use in magnetic force microscopy.

Magnetic force microscopy (MEM) is an important non-contact characterization tool for measuring magnetic fields emanating from magnetic samples, such as thin magnetic films used in magnetic recording media. In a typical MFM system, a sharp tip coated with a magnetic film is mounted on a cantilever force sensor, the tip being placed for use over the surface of the magnetic specimen while the specimen. The probe can then be scanned by a conventional XYZ scanning stage. The magnetic forces that act on the tip from the sample cause the cantilever to deflect. These deflections are monitored, typically by use of a laser detection system, the system being arranged such that deflection of the cantilever causes a displacement of a reflected laser light beam. To enhance the sensitivity, most MFM instruments oscillate the cantilever near its resonant frequency using a piezoelectric element. The magnetic force gradient exerts a force on the tip and causes the resonant frequency of the cantilever to shift. The related changes in oscillation amplitude or phase are detected and digitised to form a magnetic image of the sample. MFM using a magnetized iron tip is described by Martin et al., “High Resolution Magnetic Imaging of Domains in TbFe by Force Microscopy”, Appl. Phys. Lett., Vol. 52, No. 3, Jan. 18, 1988, pp. 244-246. The use of silicon tips coated with a film of magnetic material, such as NiFe or CoPtCr, in MFM is described by Grutter et al., “Magnetic Force Microscopy with Batch-fabricated Force Sensors”, J. Appl. Phys., Vol. 69, No. 8, Apr. 15, 1991, pp. 5883-5885.

It has been found that such conventional MFM probes have the several problems. The magnetizing direction of the tip of the probe coated with a soft-magnetic thin film of an iron/nickel alloy or the like fluctuates to become the same as the direction of the lines of the magnetic force of the surface of a sample to be detected with the probe. This arises because the soft-magnetic thin film has a small coercive force Hc. When the surface of a sample is scanned with the probe, the probe detects only the attractive force irrespective of the direction of the lines of the magnetic force of the surface. Therefore, it is not possible to specifically determine the direction of the lines of the magnetic force using such a probe. In other words, since a probe of this kind detects only the strength of the magnetic force in forming an image, it is not impossible to determine the recording condition of a vertical magnetic recording medium such as, for example, a perpendicular magnetic disk or a magneto-optical disc or the like. These recording media record information as a reversal of the direction of the magnetic force, while the strength of the magnetic force is uniform.

These problems can be partially solved by using a hard magnet as the coating. For example, as disclosed in U.S. Pat. No. 6,081,113, Eisuke Tomita and Moriya Naoto have tried to overcome these limitations of magnetic force microscopy by providing a tip coated with a cobalt/iron alloy. While this represents an improvement over known systems, it is not a complete cure. The coercivity force of cobalt/iron alloys is generally several tens of Oersted, which means that magnetization of the tip may still be affected by the fringe field from the sample surface. This will cause either magnetization reversal, as is the case with nickel/iron alloy tips or domain movement of the tip. The former will result in problems similar to those faced by the soft magnet tip, and the latter will cause extra noise to the detection signal, lowering the final resolution. Although the tip can be coated with an even harder magnet such as SmCo, this does not improve the resolution because the magnetic charges are distributed over the entire coating portion of the tip.

Another inherent problem with magnetic force microscopy that has never been satisfactorily addressed is that the tip will also affect the magnetic domains of the sample if these domains themselves include soft magnets.

In order to address the above-mentioned problems, the present invention provides a magnetic force microscopy probe having a probe tip that has a surface upon which a magnetic structure is formed, the magnetic structure including at least a ferromagnetic layer and a non-ferromagnetic layer.

In the case of an exchange coupled bias tip, the multiple layers are coated either at one side of the tip or at both sides of the tip. In the former case, prior to the coating, the conventional pyramidal tips are re-machined using a focused ion beam (FIB) to form a flat surface at one side of the tip that is perpendicular to the sample surface when it is used in an MFM scan. The coating portion is made as long as possible in the tip axis direction to allow one end of the coating portion to be placed close to the sample surface while the other is placed far away from the sample surface. The exchange-biased structure is annealed and field cooled to achieve a stable bias in the tip axis direction. A seed layer is used to enhance the exchange coupling between the ferromagnetic layer and the anti-ferromagnetic layer.

In the case of the synthetic tip, again the multiple layers are coated either at one side of the tip or at both sides of the tip. In the former case, prior to the coating the conventional pyramidal tips are re-machined using a focussed ion beam (FIB) to form a flat surface at one side of the tip that is perpendicular to the sample surface when it is used in MFM. Again, the coating portion is made as long as possible in the direction of the tip axis to allow one end of the coating portion to be put in proximity of the sample surface while the other end is relatively far away from the sample surface. The thickness of the thin non-magnetic layer may be chosen such that the two ferromagnetic layers are anti-ferromagnetically coupled. The exchange-biased structure can then be annealed and field cooled to achieve a stable bias in the tip axis direction. A seed layer may be used to enhance the exchange coupling between the ferromagnetic layer and the anti-ferromagnetic layer. Two different types of tip coatings are optionally provided by the present invention. In one case, the two ferromagnetic layers are chosen such that the magnetic moments of the two layers do not cancel one another out to allow a net magnetic charge to exist at both ends of the coatings. In the other case, the two ferromagnetic layers are chosen such that the magnetic moments of the two layers cancel one another out at all parts of the magnetic coating except for a small portion of the bottom end of the coating, where the top ferromagnet is selectively etched off using FIB. This allows the existence of a net magnetic moment only at the bottom edge of the coating, resulting in higher resolution and reduced tip/sample interaction. In the case of coating done at both sides, the magnetizations of the two ferromagnets are chosen to cancel out at all portions except for a bottom edge portion where the outer ferromagnet is selectively etched off using FIB.

The synthetic triple layer may have a net magnetization at the point of the tip and has negligible magnetic moment at other portions. When the magnetic probe is scanned across the magnetic sample, the distribution of the magnetic force on the magnetic sample is detected with very high resolution and reduced tip and sample interactions.

In embodiments of the invention, the magnetising direction of the tip may be constant and is perpendicular to the surface of the sample to be detected with the probe, irrespective of the direction of the lines of the magnetic force of the surface of the sample. This is possible because the exchange bias field can be as large as several hundred Oersteds in the exchange biased double layer; more than one order of magnitude higher than that of the cobalt/iron hard coating previously proposed. The synthetic triple layer may have an even higher bias field. Therefore, the magnetic force acting on the probe is an attractive force when the direction of the lines of the magnetic force of the surface of the sample is the same as the magnetizing direction of the probe, while it is a repelling force when the direction of the lines of the magnetic force of the surface of the sample is opposite to the direction of the magnetism of the probe. The magnetic moment of the tip can be very stable in this case, which means that no additional noise will be generated from domain wall movement of the coating materials. Hence, for example, the probe detects the non-recorded condition of a vertical magnetic recording medium as a repelling force while detecting the recorded condition of the same as an attractive force. Using a probe embodying this invention, therefore, it is possible to determine the recording condition of a vertical magnetic recording medium such as, for example, perpendicular magnetic disk, a magneto-optical disc or the like. In the case of synthetic tips, as the magnetic flux forms a close loop within the multiple layer coating and the flux only leaks from the bottom edge of the probe, the interaction between the tip and the sample is reduced.

Embodiments of the invention will now be described in detail, by way of example, and with reference to the accompanying drawings, in which:

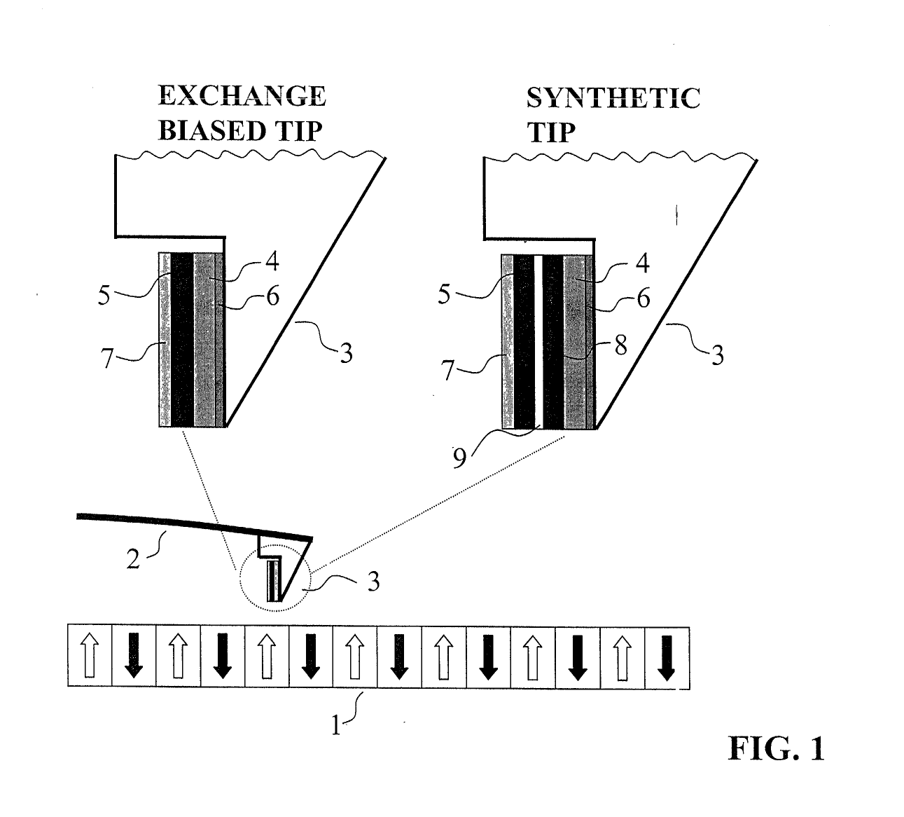

FIG. 1a is a schematic diagram of an exchange-biased tip for use in magnetic force microscopy being an embodiment of the present invention;

FIG. 1a is a diagram of a synthetic tip for use in magnetic force microscopy being an embodiment of the present invention;

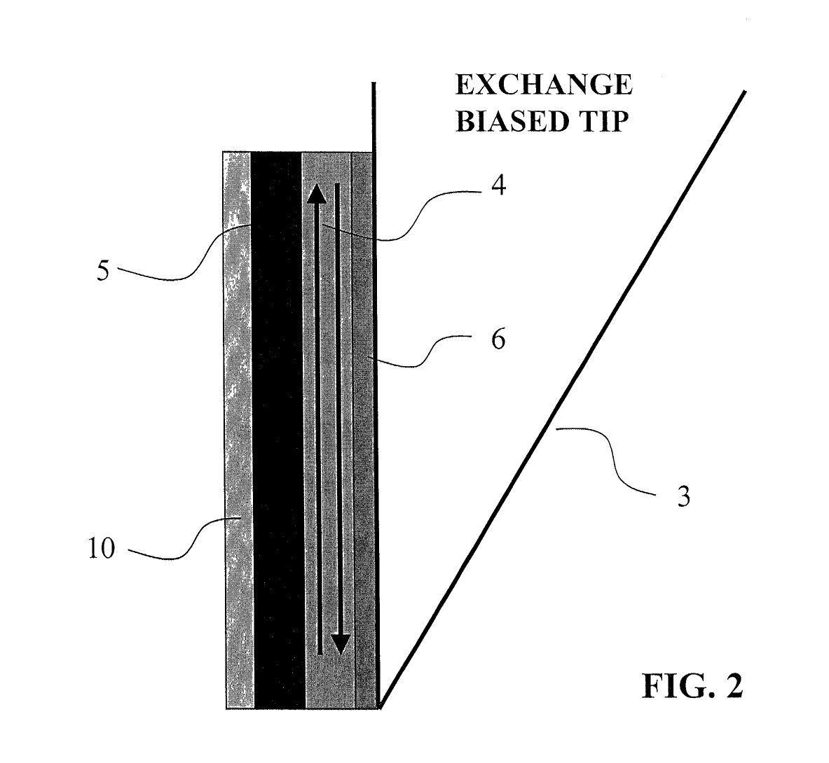

FIG. 2 is a diagram of the exchange-coupled tip of FIG. 1a showing the seed and overcoat layers, the coating being performed at one side;

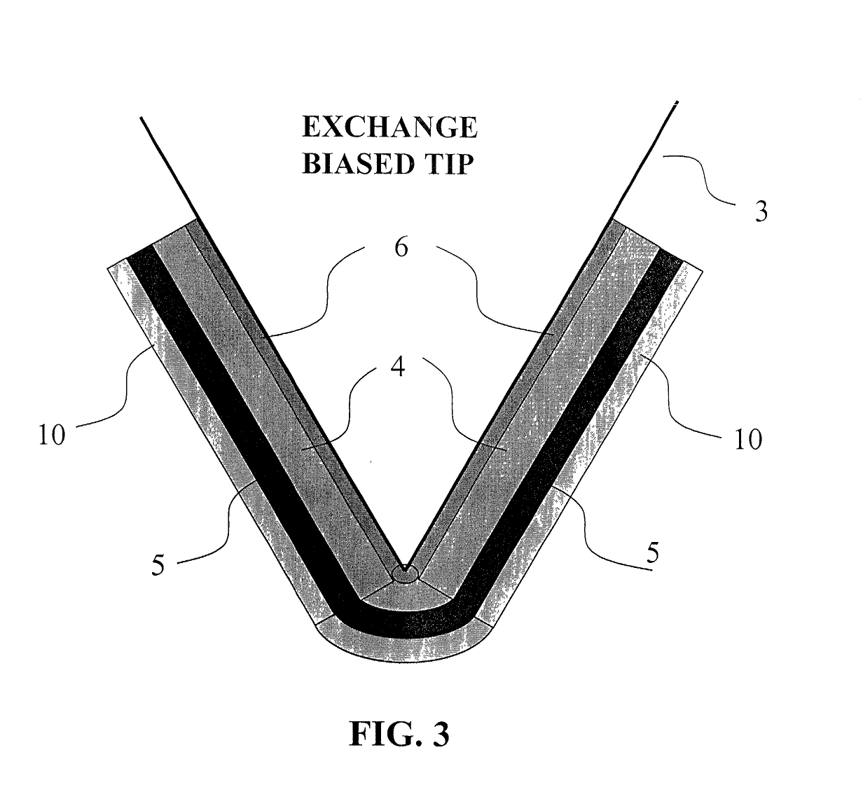

FIG. 3 is a diagram of the exchange-coupled tip of FIG. 1a where the magnetic layers are coated at both sides of the tip;

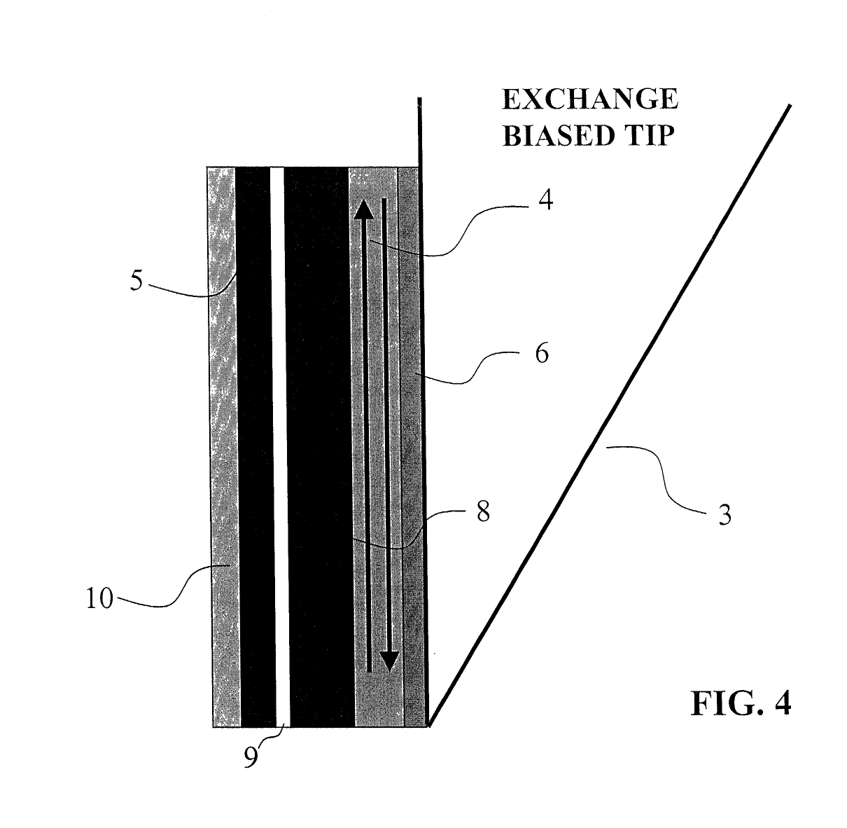

FIG. 4 is a diagram of the synthetic tip of FIG. 1b coated at one side;

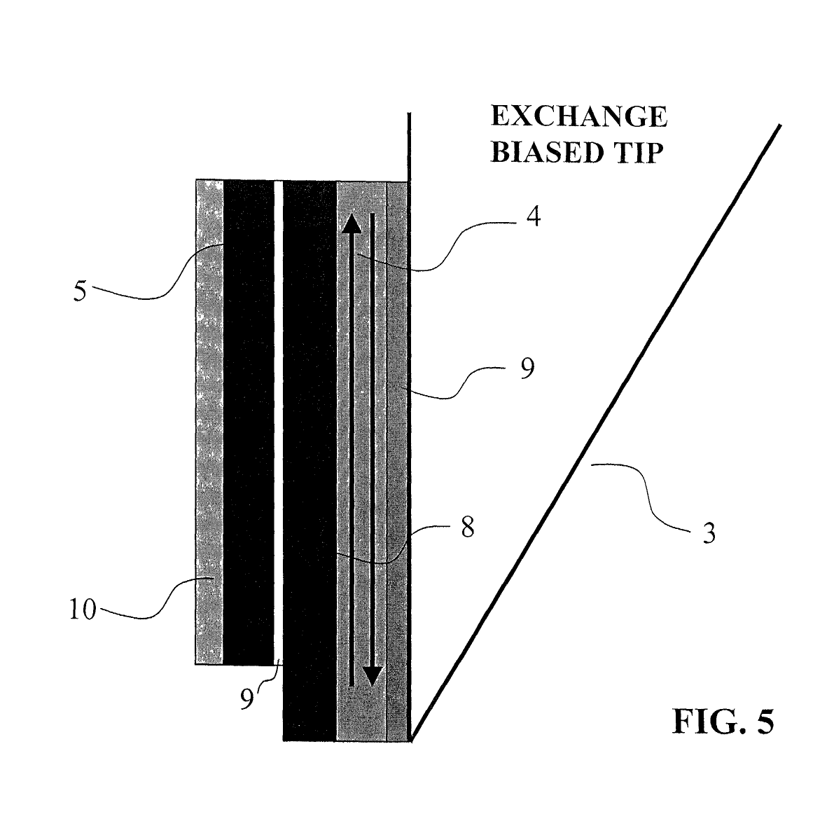

FIG. 5 is a diagram showing the synthetic tip of FIG. 1b coated at one side; and

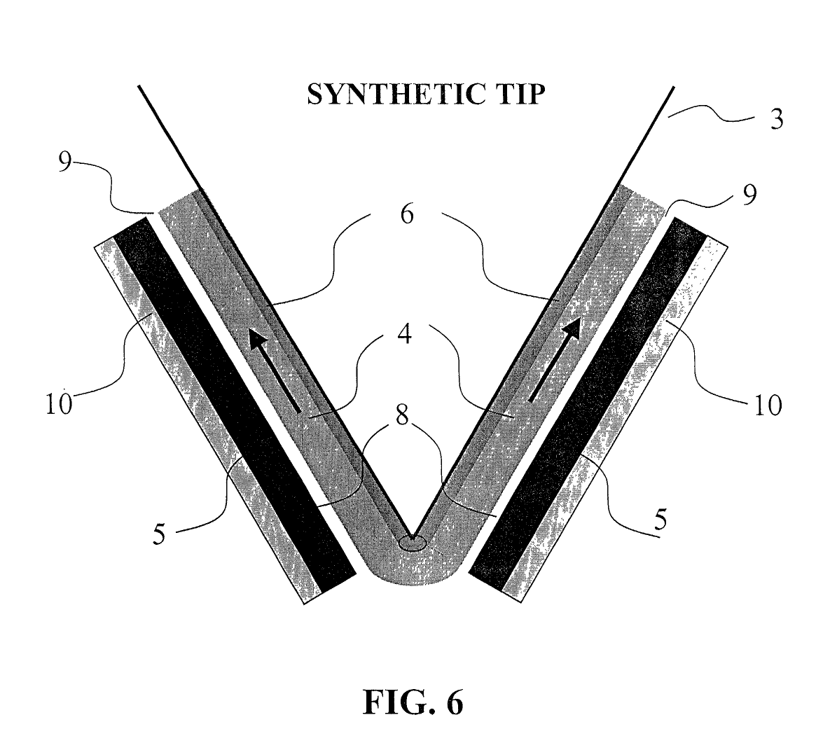

FIG. 6 is a diagram showing the synthetic tip of FIG. 1b coated at both sides.

FIG. 1 is a perspective view showing probe tips embodying the present invention to be used in magnetic force microscopy. The tip 3 attached to a cantilever 2 as is known from conventional magnetic force microscopy (MFM) apparatus. The tip 3 is coated with the multiple layers, as will be described.

The enlarged view of the tip 3 shows the structures of both the exchange coupled tip and synthetic tip in accordance with the present invention. The planar surface onto which the magnetic coatings are to be formed are produced by re-machining of a conventional pyramidal tip using the FIB. This technique is already known to those knowledgeable of the technical field. The selective coating can be performed using a lift-off process involving the following steps: dipping the conventional tip into a resist such as PMMA, baking the resist at 380K for 2 minutes, trimming the tip using FIB into desirable shape, coating the trimmed tip with the multiple layers using either evaporation or sputtering, and finally lifting off the deposited films at the non-trimmed region of the tip body.

FIG. 2 shows the enlarged view of the exchange-biased tip of the present invention to be used in magnetic force microscopy wherein the coating is performed at one side of the tip, i.e., the planar surface formed by FIB. The multiple layer structure comprises at least four layers; in this case, a tantalum seed layer 6, an IrMn anti-ferromagnetic layer 4, a CoFe ferromagnetic layer 5, and a tantalum capping layer 10. The sequence order of the ferromagnetic and anti-ferromagnetic layers can be changed. For example, the CoFc 5 layer may be deposited first and followed by the IrMn layer 4.

The coating portion is made as long as possible in the tip axis direction to allow one end of the coating portion to be put in proximity of the sample surface while the other end to be placed far away from the sample surface. The exchange-biased structure is annealed and field cooled to achieve a stable bias in the tip axis direction. The seed layer 6 is used to enhance the exchange coupling between the ferromagnetic layer 5 and the anti-ferromagnetic layer 4.

FIG. 3 shows an enlarged view of the exchange-biased tip embodying the invention to be used in magnetic force microscopy wherein the coating is performed at both sides of the tip. The multiple layer structure composes of at least four layers, in this case, a tantalum seed layer 6, an IrMn anti-ferromagnetic layer 4, a CoFe ferromagnetic layer 5, and a tantalum capping layer 10. The sequence order of the ferromagnetic layer 5 and the anti-ferromagnetic layer 4 can be changed. For example, the CoFe layer 5 may be deposited first and followed by the IrMn layer 4. The exchange-biased structure is annealed and field cooled to achieve a stable bias in the tip axis direction. The seed layer 6 is used to enhance the exchange coupling between the ferromagnetic layer 5 and the anti-ferromagnetic layer 4. The top portion of the magnetic coating can also be selectively etched off using the focused ion beam to improve the resolution.

FIG. 4 shows the enlarged view of the synthetic tip of the present invention to be used in magnetic force microscopy wherein the coating is performed only at one side of the tip. The multiple layer structure composes of at least six layers, for example, the tantalum seed layer 6, the anti-ferromagnetic layer lrMn 4, the first CoFe ferromagnetic layer 5, the ruthenium spacer layer 9, the second CoFe ferromagnetic layer 8, and the tantalum capping layer 10. The thickness of the two ferromagnetic layers 5 and 8 are chosen such that the net magnetic moment is not equal to zero. Therefore, in this case a portion of the magnetic flux from the layer with a higher flux exits at the bottom of the tip surface and interacts with the sample to detect the magnetic signal of the sample. The top portion of the magnetic coating can also be selectively etched off using FIB perpendicular to the tip axis to align the top cross-section surface of all the layers in the same plane. Again, the interaction between the tip and the sample is reduced due to the small amount of magnetic moment at the tip The resolution is also improved due to the small surface area of the net magnetic moment.

FIG. 5 shows an enlarged view of an alternative embodiment of the invention to be in which the coating is performed only at one side of the tip. The multiple layer structure composes of at least six layers, for example, a tantalum seed layer 6, an anti-ferromagnetic layer IrMn 4, a first CoFe ferromagnetic layer 5, a ruthenium spacer layer 9, a second CoPe ferromagnetic layer 8, and a tantalum capping layer 10. The thickness of the two ferromagnetic layers 5, 8 are chosen such that the net magnetic moment is zero. A small portion of the capping layer 10, the top magnetic layer 5 and the non-magnetic layer 9 are selectively etched off using FIB to expose the underlying lower ferromagnetic layer. Therefore, in this case a net magnetic flux exists at the bottom tip surface and interacts with the sample to detect the magnetic signal of the sample. Again, the interaction between the tip and the sample is reduced due to the small amount of magnetic moment at the tip. The resolution is also improved due to the small surface area of the net magnetic moment.

FIG. 6 is an enlarged view of the synthetic tip of an embodiment, in which the coating is performed at both sides of the tip. The multiple layer structure composes of at least six layers, for example, a tantalum seed layer 6, an anti-ferromagnetic layer 4, a first CoFe ferromagnetic layer 8, a ruthenium spacer layer 9, a second CoFe ferromagnetic layer 5, and a tantalum capping layer 10. The thickness of the two ferromagnetic layers is chosen such that the net magnetic moment is zero at every portion of the coating. The top ferromagnetic layer at the bottom edge is selectively etched off using the focused ion beam to expose the bottom magnetic layer. Therefore, at this localized portion, the net magnetic moment is not zero. The interaction between the tip and the sample is reduced due to the small amount of magnetic moment at the tip. The resolution is also improved due to the small surface area of the net magnetic moment.

For the formation of synthetic structures, the two ferromagnetic materials are not necessarily of same type. For example, one can be a soft magnet and the other can be a hard magnet. The multiple layers can also be formed on carbon nanotubes and other type of supporting structures.

The FIB process used in relation to embodiments of this invention can also be replaced by other batch processing techniques such as ion beam milling or reactive plasma etching. All the thin film layers used in this invention can be formed using evaporation, sputtering, and chemical vapour deposition.

What is claimed is:

1. A magnetic force microscopy probe having a probe tip that has a surface upon which a magnetic structure is formed, the magnetic structure including at least a ferromagnetic layer and a non-ferromagnetic layer.

2. A magnetic force microscopy probe according to claim 1 which the magnetic structure includes an exchange coupled ferromagnetic layer and an antiferromagnetic layer.

3. A magnetic force microscopy probe according to claim 2 in which the exchange coupled layers are deposited on a seed layer.

4. A magnetic force microscopy probe according to claim 3 in which the seed layer comprises materials selected from tantalum, copper, chromium, titanium, and diamond-like carbon.

5. A magnetic force microscopy probe according to claim 2 in which the antiferromagnetic layer comprises materials selected from manganese-based alloys of iron, nickel, iridium, platinum and oxides of cobalt, iron, nickel, and manganese.

6. A magnetic force microscopy probe according to claim 1 in which the exchange coupled layers are deposited either at one side or at both sides of the tip.

7. A magnetic force microscopy probe according to claim 1 in which the magnetic structure includes a synthetic triple layer consisting of two ferromagnetic layers separated by a non-magnetic layer.

8. A magnetic force microscopy probe according to claim 7 in which the film of synthetic triple layer comprises two ferromagnetic layers selected from the group consisting of cobalt, iron, nickel and alloys of cobalt, iron or nickel.

9. A magnetic force microscopy probe according to claim 7 in which the non-magnetic layer is sandwiched between two ferromagnetic layers.

10. A magnetic force microscopy probe according to claim 7 in which the non-ferromagnetic layer comprises a material selected from a group comprising ruthenium, copper, chromium, silver, gold, iridium, and zinc and a group of compound consisting of aluminum oxide, silicon oxide, zinc sulphide, and aluminum nitride.

11. A magnetic force microscopy probe according to claim 7 in which the non-ferromagnetic layer is exchange coupled to either the inner ferromagnetic layer or the outer ferromagnetic layer.

12. A magnetic force microscopy probe according to claim 7 in which the thickness of the non-magnetic layer is chosen to render the magnetizations of the two ferromagnetic layers to be aligned anti-parallel to each other.

13. A magnetic force microscopy probe according to claim 7 in which the magnetizations of the two ferromagnets are cancelled out at all portions except for an end portion of the tip.

14. A magnetic force microscopy probe according to claim 7 in which the outer ferromagnet is selectively etched off using focused ion beam when the coating is performed at both sides.

15. A magnetic force microscopy probe according to claim 7 in which the magnetizations of the two ferromagnetic layers are disposed to not cancel out with each other and an opening is made at the bottom-end of the probe to allow a part of the flux to leak out from the tip.

16. A magnetic force microscopy probe according to claim 7 in which the magnetizations of the two ferromagnets are selected to not cancel out with each other when the coating is performed at one side of the tip.

17. A magnetic force microscopy probe according to claim 1 in which the magnetic structure is formed on a generally planar part of the tip.

18. A magnetic force microscopy probe according to claim 1 in which the magnetic structure is of substantially uniform thickness.

19. A magnetic force microscopy probe according to claim 1 in which the magnetic structure further includes a capping layer.

20. A magnetic force microscopy probe according to claim 19 in which the capping layer comprises materials selected from tantalum, aluminum, copper, chromium, titanium, silicon oxide, silicon nitride, and diamond-like carbon.

21. A magnetic force microscopy probe according to claim 1 in which the ferromagnetic layer includes materials selected from the group consisting of cobalt, iron, nickel and alloys of cobalt, iron or nickel.

22. A magnetic force microscopy probe according to claim 1 in which a ferromagnetic layer is exchange coupled to an anti-ferromagnetic layer to stabilize its magnetization.

23. A magnetic force microscopy probe according to claim 22 in which the antiferromagnetic layer is composed of materials selected from the manganese-based alloys of iron, nickel, iridium, platinum and oxides of cobalt, iron, nickel, and manganese.

24. A magnetic force microscopy probe according to claim 1 in which the layers coatings are formed on carbon nanotubes, silicon nanowires, or other nanometer scale supporting wires.

25. A magnetic force microscopy probe according to claim 1 in which the layers are formed in nanometer scale holes or depression form on conventional pyramidal tips.
